(19) United States
(12) Patent Application Publication
(10) Pub. No.: US 2006/0160369 A1
(43) Pub. Date: Jul. 20, 2006

(54) Method of fabricating semiconductor electric heating film

(76) Inventor: Cheng Ping Lin, Taipei (TW)

Correspondence Address: LOWE HAUPTMAN BERNER, LLP, 1700 DIAGONAL ROAD, SUITE 300, ALEXANDRIA, VA, 22314, US

(21) Appl. No.: 11/037,238

(22) Filed: Jan. 19, 2005

(51) Int. Cl. H01L 21/31; C23C 14/20; H01L 21/469

(52) U.S. Cl. 438/758; 427/525

(57) ABSTRACT

Disclosed is method of fabricating semiconductor heater film which is formed on a substrate with excellent heat resistant and electrical insulation property by depositing atomized particles of coating material essentially formed of powdered metallic (Sn,V) chlorides and silicide mixed with one of Fe, Sb or In compound and solvent such as water, methyl and ethyle alcohols, hydrochloric acid, sulfuric acid, also small amount of non-organic acid is added to intensify the chemical affinity of the coating material.

### BACKGROUND OF THE INVENTION

1. Field of the invention

The present invention relates to method of fabricating a semiconductor heating film.

2. Description of the prior art

The conventional electric heating utilizes heating coils for producing heat energy when being connected to a power supply. However, the heating coils need high manufacturing cost because a tedious winding process is required.

The heating coils, such as the coils made of coils or strands of nichrome wire, generate red hot heat energy by consuming heavy electrical power and a large amount of ambient oxygen that leads to degrading the quality of environmental atmosphere. Meanwhile, the heating unit generating the red hot heat energy is not suitable to be installed in the oil fields located in the frigid zone.

As the remarkable progress in the semiconductor technology has been accomplished in these years, the heating equipment made of semiconductor material has gradually replaced the conventional heating material such as resistive coils or strands of nichrome wire by the reason that the former is superior to the latter in many respects such as heat production efficiency, capable of operating securely at higher temperature without generating red fire, consuming less electrical power etc.

Among several patents related to the semiconductor heating film approved in China and Taiwan. One of them filed on Mar. 6, 2002 in China as CN No. 1,380,443 disclosing “Technique of Controlling Pasty Condition of the material for forming a Semiconductor Electric Heating Film.” Wherein the remedy is provided in order to eliminate the shortcoming inherent to the prior semiconductor electric heating film fabrication which being unable to obtain products with uniform quality due to failure in properly controlling the temperature and efficiency of forming the film during carrying the process of vaporization of the liquid coating material with high temperature and injecting to a substrate set in a furnace to form an electric heater material. According to this cited case, the information as to temperature condition of the substrate set in the furnace is instantaneously transmitted to a control station so as to enable the control station to deliver a signal to control efficiency of forming the film. The cited invention disclosed the steps of fabrication as follows:

1. Transmitting the information about the thickness of film which has been formed on the substrate set in the furnace to the control station.

2. Transmitting the information about the coating pressure to the control station.

3. Outputting a signal from the control station to control the distance between the injection nozzle and the substrate.

4. Outputting a signal from the control station for controlling the moving speed of the substrate.

5. Outputting a signal from the control station for controlling injection of fluidal coating material.

A Taiwanese company, Ho Li Co. Ltd, has disclosed “Electric Heating Film and Electrodes of the Same”, which was patented in Taiwan with application No. 90126142 filed on Oct. 23, 2001. According to this invention, it is aimed to eliminate the shortcoming inherent to the prior art in which rectangular upper and lower electrodes are each attached to one of the two sides of the film. When the current built up by a bias voltage flows through the film, the current flow is larger in the middle portion of the film than that in the two sides. Such non-uniform current distribution in the electric heating film leads to a result overheating in the middle portion and loweiing the heating efficiency at both sides.

The second cited invention was made for rectifying the above shortcoming by adjusting the width and disposing aspect of the film. This invention provided means by laying more than one electric heating film between more than one pair of electrodes, wherein the width of the paired electrode is larger in the two sides than in the middle portion so as to adjust current density in the electric heating film as uniform as possible by reducing the resistance between two sides of the paired electrodes so that the problem of overheating in the middle portion of the film and lowering the heating efficiency at both sides thereof can be solved. Meanwhile, the edge profile of connection between the paired electrodes and the film is arcuate or sinuous “Method of Fabricating Semiconductor Electric Heating Film” which was patented in Taiwan and was filed on Apr. 26, 1993 with filing No. 82,103,268 described the following disadvantages in the prior art. “The conventional ohmic heating element has inherent disadvantages such as consuming large electric power, easy to oxidate, fragile etc. that leads to raise up entire cost including installation maintenance and fabrication. Besides, the ceramic heater element (PTC) has a large inrush current. The price of its raw material is expensive and requires long fabrication time yet with poor yield so that it is as disadvantageous as that for the ohmic heater element.”

For eliminating the disadvantages of the prior arts, the third cited invention provided the method of fabricating semiconductor electric heating film in which the following steps are included:

1. Employing one of the metallic (Au, Ag, Sb) oxides, or organic compounds as an elementary material and mixing 1˜10% (weight ratio) of one of the compounds of Sb, Fe and F as an additive to prepare a main coating material;

2. Mixing 20-60% (weight ratio) of solvent one selected from water, methyl alcohol, ethyl alcohol, hydrochloric acid, ethylamine . . . etc. The main coating material prepared in step (1);

3. Employing one of the high voltage withstanding and low expansion coefficient materials selected from quart, glass, ceramic and mica to form a substrate, and dry its surface with fire after being cleaned with pure water; and

4. Setting the substrate been treated in a furnace and activating its surface with high temperature, then injecting the atomized coating material into the furnace and depositing the ionized particles of the coating material on the surface of the substrate thereby completing the formation of a semiconductor electric heating film.

Here, the flow chart of the fabricating process can be concluded as: mixing the additive in the metallic compound elementary coating materials→adding the solvent in the coating material as prepared in the preceding steps→cleaning the substrate surface→depositing the atomized coating material on the substrate to form an electric heating film.

Although the three fabrication methods of the semiconductor electric heating film exemplified above have individual progressive advantages, yet all three cited cases are by no means perfect if the precision and excellency of the product quality if considered.

### SUMMARY OF THE INVENTION

The present invention is aimed to rectify these defects noticeable on the prior art. Accordingly, the object of the present invention is to provide a novel method of fabricating semiconductor electric heating film with which to produce a semiconductor heating film which can operate at high temperature safely with a better heat production efficiency yet less power consumption and lower fabrication cost. To achieve this object, the method of fabrication thereof comprising the following steps of: preparing an elementary material from one of the metallic (Sn, V) chlorides or silicides, into which further one of the compounds of Fe, Sb or In, with an amount of 0.01˜1% (weight ratio) of the elementary material; adding a prescribed amount of solvent, and churning the resultant solution uniformly; adding small amount of non-organic acid into the solution prepared in the preceding step so as to oxidate or reduce the elementary material thereby to obtain finish coating material; cleaning a substrate with supersonic wave and then washing with pure water in order; setting the washed substrate in a furnace and heating the substrate with the in-line heating process gradually; and, as soon as the surface of the substrate has reached the dual state temperature, depositing high temperature atomized and ionized particles of the finished coating material on the surface of the substrate so as to form a layer of film using a nozzle made of non-ferrous acid-proof and alkali-proof substance.

In the present invention, water, methyl alcohol, ethyl, and hydrochloric acid can be used as solvent. The substrate is made of high temperature withstanding, electrically insulating, with low expansion coefficient material such as enamel quartz, glass and ceramic . . . etc. The applied temperature is 500˜1000° C. for 1˜10 min. The thickness of film is 0.5˜5 μm.

### BRIEF DESCRIPTION OF THE DRAWINGS

The accompanying drawing, which is included to provide a further understanding of the invention, and incorporated in and constitute a part of this specification, illustrate embodiments of the invention and together with the description serve to explain the principles of the invention, wherein:

FIG. 1 is a front view of an electric heating unit in which the semiconductor electric heating film of the present invention is installed.

FIG. 2 is a sectional view of an electric heating unit in which the semiconductor electric heating film of the present invention is installed.

### DETAILED DESCRIPTION OF THE PREFERRED EMBODIMENT

Herein below, a preferred embodiment of the present invention will be described in conjunction with the attached drawings so that the progressiveness and advantages of the present invention can be thoroughly understood.

In preparing the coating material to form the semiconductor film, the metallic chloride of Sn or V and a silicide is selected as an elementary material, in which 0.01˜1% C (weight ratio) of the elementary material from one of the powdered compounds of Fe, Sb or In, is mixed uniformly into the elementary material. Then, a prescribed amount of solvent, preferably 10˜30% of the sum of elementary material plus mixed material, is added and the solution is churned uniformly. Here, the elementary material is preferably in powdered state.

After the above solution is homogeneously churned, a small amount of non-organic acid selected one from nitric acid, sulphuric acid and hydrochloric acid is added so as to intensify the chemical affinity of the elementary material and facilitate oxidation and reduction thereof.

Then afterwards the substrate is cleaned with supersonic wave and pure water in order before it is set in a furnace and heated with high temperature by in-line process. As soon as its surface has reached the dual state temperature, a layer of film formed of high temperature particles of atomized ions is deposited thereon by injection from a nozzle which is made of a non-ferrous acid-proof and alkali-proof substance.

In the present invention, water, methyl alcohol, ethyl alcohol, surfuric acid and hydrochloric acid are used as solvent. The substrate is made of high temperature withstanding, electrically insulating and low expansion coefficient material such as enamel, quartz, glass and ceramic. The applied temperature is 500˜1000° C., for 1˜10 min. The thickness of film is 0.5˜5 μm, and the thickness of the substrate is optional according to the actual needs.

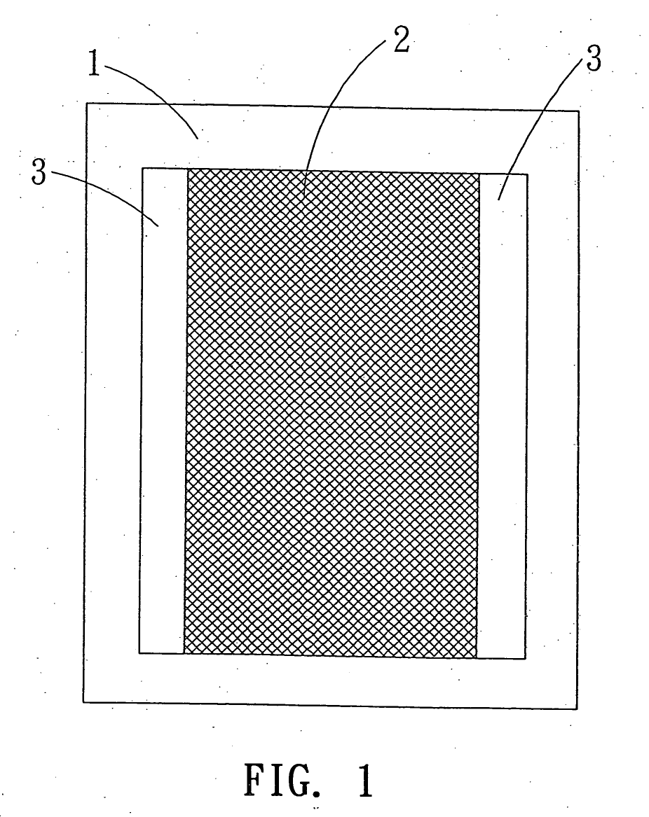

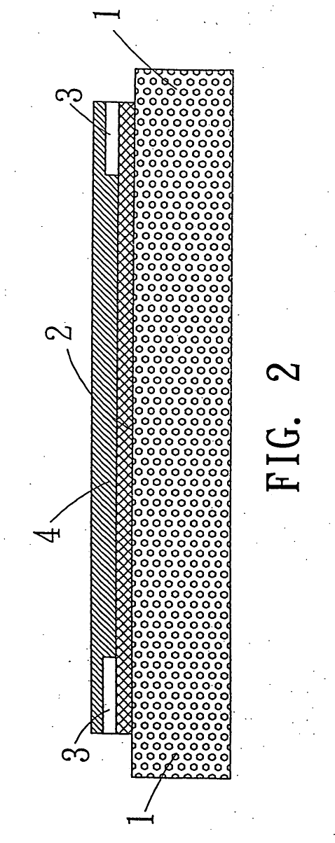

As for how to apply the semiconductor electric heating film of the present invention in an electric heating unit, illustration is made with reference to FIGS. 1 and 2. The film 2 of the present invention is laid on one surface of a substrate 1, and each side of the film 2 is attached with an electrode 3 which is electrically in connection with the film 2. By supplying electric power to the electrodes 3, the film 2 with its substrate 1 is activated to emit far infrared ray so as to heat the inner part of a heated subject uniformly.

Besides, a heat insulation layer 4 made of non-organic material may be formed on the electric heating film 2. By so since the heat is applied to the opposite surface of that where the film 2- is formed, the heat insulation layer 4 may well serve to prevent dissipation of useful energy.

It emerges from the above description that the semiconductor electric heating film fabricated according to the present invention can rectify the noticeable defects inherent to the products fabricated according to the prior arts. The heating film of the present invention is sure to be able to operate at high temperature securely with an excellent heat production efficiency yet less power consumption and lower production cost.

Those who are skilled in the art will readily perceive how to modify the invention. Therefore, the appended claims are to be construed to cover all equivalent structures which fall within the true scope and split of the invention.

What is claimed is:

1. Method of fabricating semiconductor electric heating film including the steps of:
Preparing an elementary material from one of the metallic (Sn,V) chlorides and a silicide, into which further mixing one of the compounds of Fe, Sb or In with an amount of 0.01˜11% (weight ratio) of said elementary material;
Adding a prescribed amount of solvent, and churning the resultant solution uniformly;
Adding small amount of non-organic acid into the solution prepared in the preceding step so as to oxidate or reduce said elementary material thereby obtaining a finished coating material;
Cleaning a substrate with supersonic wave and then washing with pure water in order;
Setting said washed substrate in a furnace and heating said substrate with the in-line heating process gradually; and as soon as the surface of said substrate has reached the dual state temperature, depositing high temperature atomized and ionized particles of said finished coating material on the surface of said substrate so as to form a layer of film using a nozzle made of non-ferrous acid-proof and alkali-proof substance.

2. The method as claimed in claim 1, wherein said solvent is one selected from water, methyl-alcohol, ethyl-alcohol, hydrochloric acid and sulfuric acid.

3. The method as claimed in claim 1, wherein said substrate is made of high temperature withstanding, electrically insulating and low expansion material one selected from enamel, quartz, glass and ceramic . . . etc.

4. The method as claimed in claim 1, wherein said heating process is performed at the temperature 500˜1000° C. for 1˜10 min.

5. The method as claimed in claim 1, wherein the thickness of film form on the surface of said substrate is 0.5˜5 μm.

6. The method as claimed in claim 1, wherein the amount of solvent to be added is 10˜30% (weight ratio) of the sum of said elementary material plus mixtures.

7. The method as claimed in claim 1, wherein said elementary material is in powdered state.

8. The method as claimed in claim 1, wherein said non-organic acid is one selected from nitric acid, sulfuric acid, and hydrochloric acid.
